(19) United States
(12) Patent Application Publication
(10) Pub. No.: US 2007/0114515 A1
(43) Pub. Date: May 24, 2007

(54) NITRIDE SEMICONDUCTOR DEVICE HAVING A SILVER-BASE ALLOY ELECTRODE

(75) Inventors: Hidekazu Aoyagi, Niiza-shi (JP); Tetsuji Matsuo, Niiza-shi (JP); Tetsuji Moku, Niiza-shi (JP); Mikio Tazima, Niiza-shi (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: Sanken Electric Co., Ltd., Niiza-shi (JP)

(21) Appl. No.: 11/623,257

(22) Filed: Jan. 15, 2007

(30) Foreign Application Priority Data
Jul. 13, 2005 (JP) PCT/JP05/12900
Jul. 28, 2004 (JP) 2004-220822

(51) Int. Cl. H01L 29/06

(52) U.S. Cl. 257/13

(57) ABSTRACT

An LED is disclosed which comprises a nitride-made main semiconductor region formed on a substrate for generating light, and an electrode formed on the main semiconductor region to a thickness sufficiently small to transmit the light from the main semiconductor region. The electrode is made from a silver-base alloy, rather than from silver only, that contains an additive or additives selected to protect the electrode against oxidation and/or sulfurization and to enhance the chemical stability of the electrode without loss in contact ohmicity.

### CROSS REFERENCE TO RELATED APPLICATIONS

This is a continuation of Application PCT/JP2005/012900, filed Jul. 13, 2005, which claims priority to Japanese Patent Application No. 2004-220822 filed Jul. 28, 2004.

### BACKGROUND OF THE INVENTION

This invention relates to nitride semiconductor devices including light-emitting diodes (LEDs) and other electronic devices. More specifically, the invention deals with electrodes of improved compositions for such semiconductor devices.

LEDs have been known which have their main semiconductor region, where light is generated, made from nitride semiconductors such as gallium nitride. Some such LEDs employ a silver electrode on the light-emitting surface of the main semiconductor region. The silver electrode is made as thin as 20 nanometers or less in order to transmit the rays of light generated in the main semiconductor region. Japanese Unexamined Patent Publication No. 11-186599 is hereby cited as teaching the silver electrode. When made 20 nanometers or less in thickness, the silver electrode permits the passage of light rays in a wavelength range of 350-600 nanometers. The transmittance is particularly high (e.g., 60 percent or more) for wavelengths up to 400 nanometers. The silver electrode on the nitride semiconductor LEDs has been favored additionally because it makes fairly good ohmic contact with nitride semiconductors, even with those of p type which are higher in electrical resistivity.

It is thus seen that the silver electrode with the noted properties makes it fit for use on the light-emitting surface of the LED. Transparency is not required for use of silver electrodes on field-effect transistors (FETs) and other non-light-emitting semiconductor devices. Ohmic contact with the main semiconductor regions of such devices is still required for the electrodes thereon. Silver electrodes do meet this requirement.

Silver, however, is chemically unstable at temperatures as low as 10-100° C. and susceptible to oxidation or sulfurization. The silver electrode on oxidation or sulfurization results in an increase in contact resistance with the nitride-made main semiconductor region and hence in the deterioration of the electrical characteristics of the device. It is also a weakness of silver electrodes that they are easy to aggregate or cohere into flocs in the course of fabrication by vapor deposition.

### SUMMARY OF THE INVENTION

The present invention has it as an object to defeat all the noted shortcomings of conventional silver electrodes on nitride LEDs and other semiconductor devices.

Briefly, the invention may be summarized as a nitride semiconductor device comprising a main semiconductor region made from a nitride or nitrides, and an electrode formed on the main semiconductor region. The electrode is made from a silver-base alloy containing at least one additive selected from the group consisting of gold, copper, palladium, neodymium, silicon, iridium, nickel, tungsten, zinc, gallium, titanium, magnesium, yttrium, indium, and tin.

For the best results the additive or additives may be contained in the silver-base alloy in a proportion ranging from 0.5 percent by weight to 10 percent by weight.

More specifically, the silver-base alloy may contain at least one first additive selected from among gold, copper, palladium, iridium and nickel in order to resist oxidation, and at least one second additive selected from among gold, neodymium, silicon, tungsten, zinc, gallium, titanium, magnesium, yttrium, indium, and tin in order to resist sulfurization. The first and the second additives may be each contained in the silver-base alloy in a proportion, and both contained in the silver-base alloy in a total proportion, ranging from about 0.5 percent by weight to about 10 percent by weight with respect to that of silver.

Thus the invention provides a nitride semiconductor device having an improved silver-base alloy electrode which is protected specifically against oxidation or sulfurization, or against both, depending upon the particular additive or additives employed. The silver-base alloys according to the invention are also well suited for use as electrodes of nitride semiconductor devices by virtue of their low contact resistance with the main semiconductor regions.

The above and other objects, features and advantages of this invention will become more apparent, and the invention itself will best be understood, from a study of the following description and appended claims, with reference had to the attached drawings showing some preferable embodiments of the invention.

### BRIEF DESCRIPTION OF THE DRAWINGS

FIG. 1 is a schematic sectional illustration of an LED embodying the principles of the invention.

FIG. 2 is a similar illustration of another preferred form of LED according to the invention.

FIG. 3 is a similar illustration of still another preferred form of LED according to the invention.

### DESCRIPTION OF THE PREFERRED EMBODIMENTS

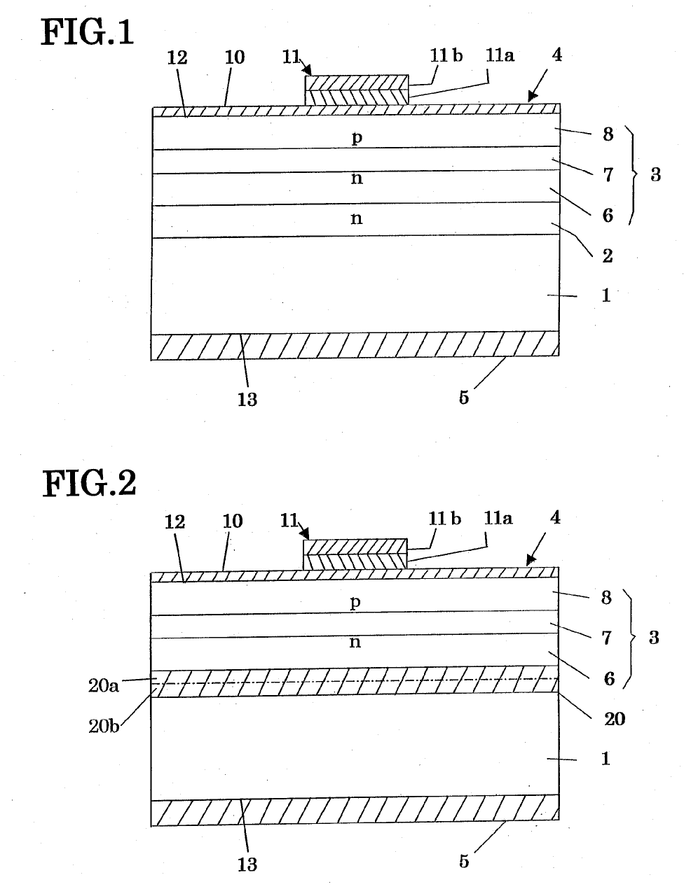

The invention will now be described more specifically as embodied in the LED shown diagrammatically in FIG. 1. The representative LED broadly comprises:
1. An electroconductive silicon substrate 1.
2. A buffer layer 2 on one of the pair of opposite major surfaces of the substrate 1.
3. A main semiconductor region or light-generating semiconductor region 3 on the buffer layer 2 made from nitride semiconductors for generating light.
4. A top electrode or anode 4 on the top surface of the main semiconductor region 3.
5. A bottom electrode or cathode 5 covering the complete underside, or the other of the pair of opposite major surfaces, of the substrate 1.

The main semiconductor region 3 is shown as having an undoped nitride semiconductor active layer 7 confined between a pair of doped nitride semiconductor claddings 6 and 8 of opposite conductivity types for providing a double heterojunction LED. More will be said presently about this main semiconductor region 3. The buffer layer 2 might be considered a part of the main semiconductor region 3.

The silicon substrate 1 gains an n-type conductivity by being doped with an n-type impurity to a concentration of from 5×10¹⁸ cm⁻³ to 5×10¹⁹ cm⁻³. This substrate 1 is therefore electrically conducting, being as low in resistivity as from 0.0001 ohm-centimeter to 0.0100 ohm-centimeter, thus providing part of the current path between anode 4 and cathode 5. The substrate 1 must be sufficiently thick (e.g., 300-1000 micrometers) and strong to mechanically support the overlying buffer layer 2 and main semiconductor region 3.

The buffer region 2 of n type is grown in vapor phase on the substrate 1. Preferably, despite the showing of FIG. 1, the buffer region 2 is multilayered, comprising for example a plurality or multiplicity of alternating AlN and GaN layers.

The n-type nitride cladding 6, undoped nitride active layer 7, and p-type nitride cladding 8 of the main semiconductor region 3 are successively grown in vapor phase on the buffer region 2 in order to provide an LED of the familiar double heterojunction design. In this embodiment the lower cladding 6 of the main semiconductor region 3 is made from any of the nitride semiconductors of the following general composition plus an n-type dopant:
AlₓIn_{y}Ga_{1-x-y}N
where the subscripts x and y are both numerals that are equal to or greater than zero and less than one. The lower cladding 6 of this particular embodiment is made from n-type GaN (both x and y are zero in the formula above).

The active layer 7 is fabricated from any of undoped nitride semiconductors that are generally expressed as:
AlₓIn_{y}Ga_{1-x-y}N
where the subscripts x and y are both numerals that are equal to or greater than zero and less than one. The active layer 7 of this particular embodiment is made from InGaN (x=0). In practice the active layer 7 may preferentially take the form of the familiar multiple quantum well structure, although a single quantum well construction is adoptable as well. Optionally, the active layer 7 may be doped with a p- or n-type conductivity determinant. It is even possible to eliminate the active layer 7 altogether and to place the p-type semiconductor layer 8 in direct contact with the n-type semiconductor layer 6.

The upper cladding 8 of the active layer 7 is made from any of the nitride semiconductors of the following general composition plus a p-type dopant:
AlₓIn_{y}Ga_{1-x-y}N
where the subscripts x and y are both numerals that are equal to or greater than zero and less than one. The upper cladding 8 of this embodiment is made from p-type GaN (x=0, y=0).

The anode 4 is shown as a combination of a transparent overlay 10 and a bonding pad 11. The transparent overlay 10 covers the complete top surface of the main semiconductor region 3, or of its p-type nitride semiconductor cladding 8, and makes ohmic contact therewith. The transparent overlay 10 serves the dual purpose of making low resistance contact with the main semiconductor region 3 and transmitting the light generated therein. Covering the complete top surface of the main semiconductor region 3, the transparent overlay 10 can cause current flow not only through its part right under the bonding pad 11 but throughout its remainder which is out of register with the pad.

The anode overlay 10 is made from a silver-base alloy according to the novel concepts of this invention and so gains both transparency and contact ohmicity without the noted shortcomings of the prior art silver electrode. The silver-base alloys employable for the purposes of the invention should be 90.0-99.5 weight percent silver for the best results, containing 0.5-10.0 weight percent of an additive or additives set forth below. The additive or additives should be capable of saving the anode overlay from oxidation and/or sulfurization without impairment of transparency and contact ohmicity. The anode overlay 10 is from one nanometer to 20 nanometers thick and permits the passage of light rays in a wavelength range of 400-600 nanometers.

Additives meeting all such requirements include copper (Cu), gold (Au), palladium (Pd), neodymium (Nd), silicon (Si), iridium (Ir), nickel (Ni), tungsten (W), zinc (Zn), gallium (Ga), titanium (Ti), magnesium (Mg), yttrium (Y), indium (In), and tin (Sn). Out of these, gold may be employed to prevent both oxidation and sulfurization. Either one or more of copper, gold, palladium, iridium, and nickel may be employed to prevent oxidation. Either one or more of gold, neodymium, silicon, tungsten, zinc, gallium, titanium, magnesium, yttrium, indium, and tin may be employed to prevent sulfurization. The foregoing two groups of elements may be employed in selected combinations to prevent both oxidation and sulfurization. The anode overlay 10 on oxidation and/or sulfurization would fail to make good ohmic contact with the main semiconductor region 3, resulting in an increase in forward voltage drop between anode 4 and cathode 5.

Of the additives listed above, indium, tin, titanium, palladium, and nickel are particularly conducive to the better coherency of the main semiconductor region 3, anode overlay 10 and bonding pad 11. One or more of these elements may therefore be employed to that end, in addition to another additive or additives adopted for preclude oxidation and/or sulfurization.

Generally, the higher the proportion of an additive or additives contained in the silver-base alloy, the less will the oxidation or sulfurization of the anode overlay, as well as the aggregate or coagulation of silver at the time of its vapor deposition, occur. However, the contact resistance between main semiconductor region 3 and anode overlay 10 will become higher in proportion with the additive content of the silver-base alloy. The proportion of the additive or additives in the silver-base alloys according to the invention may therefore be so determined that the resulting contact resistance between main semiconductor region 3 and anode overlay 10 is not more than that of the prior art LEDs employing the anode overlay made solely from silver with its susceptibility to oxidation and sulfurization.

From the foregoing considerations it is hereby suggested that the proportion of the additive or additives in the silver-base alloys according to the invention be from 0.5-10.0 percent by weight. The additive or additives when contained in proportions of less than 0.5 percent by weight would fail to save the anode overlay from oxidation or sulfurization. Should the additive content exceed 10.0 percent by weight, on the other hand, then the contact resistance would not become so low as could be desired. The additive proportion is preferably 1.5-5.0 percent by weight, and most desirably 3.5-4.5 percent by weight.

A test LED was made in which the anode overlay 10 was formed by depositing a silver-base alloy containing four weight percent gold on the preformed p-type semiconductor cladding 8 of the main semiconductor region 3. After conventionally creating the bonding pad 11 on the thus formed anode overlay 10, the complete article was heated to 500° C. The forward voltage between anode 4 and cathode 5 of this test LED during the flow of a forward current of 30 milliamperes was 3.5 volts.

Another test LED was made by the same method as above except that the anode overlay 10 was of a silver-base alloy containing two weight percent copper and two weight percent zinc. The forward voltage of this second test LED during a forward current flow of 30 milliamperes was 3.6 volts.

Still another test LED was made by the same method as above except that the anode overlay 10 was of a silver-base alloy containing four weight percent copper. The forward voltage of this third test LED during a forward current flow of 30 milliamperes was 3.55 volts.

Yet another test LED was made by the same method as above except that the anode overlay 10 was of a silver-base alloy containing four weight percent zinc. The forward voltage of this fourth test LED during a forward current flow of 30 milliamperes was 3.65 volts.

A prior art test LED was made by way of comparison by the same method as above except that the anode overlay was solely of silver. The forward voltage of this prior art test LED during a forward current flow of 30 milliamperes was 3.7 volts.

Another prior art test LED was made by the same method as above except that the anode overlay was a lamination of a silver and a titanium dioxide layer. The forward voltage of this second prior art test LED during a forward current flow of 30 milliamperes was 3.8 volts.

The bonding pad 11 on the anode overlay 10, to which wire or like conductor is to be conventionally bonded, is shown as a combination of a titanium layer 11ₐ directly overlying the anode overlay and a gold layer 11_{b} on the titanium layer. Being opaque, the bonding pad 11 is compactly placed centrally upon the anode overlay 10, which may be square shaped as seen in a plan view, for minimal interference with the emission of light from the anode overlay. The anode overlay 10 is electrically coupled to the bonding pad 11 for uniform current flow throughout the main semiconductor region 3.

The cathode 5 is formed on the underside 13 of the silicon substrate 1 in ohmic contact therewith. The cathode could, however, be disposed on the substrate 1, or on the buffer layer 2, or even on the n-type cladding 6 of the main semiconductor region 3.

In operation the active layer 7 of the main semiconductor region 3 will generate light upon application of a forward voltage between anode 4 and cathode 5. The light will travel from the active layer 7 in part toward the anode 4 and in part toward the cathode 5. Radiated toward the anode 4, the light fraction will directly emerge from the LED through that part of the anode overlay 4 which is left uncovered by the bonding pad 11. The part of the light that has been radiated toward the cathode 5 will be thereby reflected and likewise emerge from the LED.

The advantages gained by this embodiment of the invention may be recapitulated as follows:
1. Made from any of the silver-base alloys suggested by the invention, the anode overlay 10 is protected against oxidation and/or sulfurization, and kept from aggregate or coagulation at the time of its fabrication, by virtue of the additive or additives contained in the alloy.
2. The anode overlay 10 has low contact resistance with the nitride semiconductor region 3.
3. The anode overlay 10 is favorable in both transparency and ohmicity.
4. The anode overlay 10 does not require the provision of an overlying titanium dioxide layer suggested by the Japanese unexamined patent application, supra, and so is simpler in construction and easier and more economical of manufacture.

### Embodiment of FIG. 2

The LED shown in FIG. 2 by way of another preferred embodiment of the invention is akin to the FIG. 1 embodiment except for the absence of a buffer region from between silicon substrate 1 and main semiconductor region and the provision of a reflector layer 20 in its stead. The reflector layer 20 may be made from the same silver-base alloy as is the anode overlay 10 for the best results, but may also be made from silver or other metals or take the form of a lamination of semiconductor sublayers. The reflector layer 20 of this particular embodiment is formed by pressing two silver-base alloy sublayers 20ₐ and 20_{b} against each other in a temperature range of 250-400° C. Such unification of two sublayers under heat and pressure results in the diffusion of the constituent metals from each sublayer into the other.

The reflector layer 20 may be not less than 50 nanometers thick purely to prevent the passage of light on to the silicon substrate 1 but not less than 80 nanometers thick to assure firm adhesion of the main semiconductor region 3 to the substrate. However, if 1500 nanometers or more in thickness, the reflector layer 20 might crack. The reflector layer 20 should therefore be about 50-1500 nanometers, preferably about 80-1000 nanometers, thick.

Thus, in this alternate embodiment, it is the reflector layer 20, not the cathode 5 of the FIG. 1 embodiment, that reflects the light fraction that has been radiated in a direction away from the anode 4. This light fraction need not travel through the buffer layer 2 and substrate 1 as in FIG. 1 but is directly reflected by the reflector layer 20 for emission from the surface 12 of the main semiconductor region 3.

A higher efficiency of light emission realized by the reflector layer 20 is among the advantages of this embodiment. It is of course understood that the anode overlay 10 is made from any of the same silver-base alloys as set forth in conjunction with its FIG. 1 counterpart and so offers the same advantages therewith.

This embodiment possesses additional advantages in both performance characteristics and manufacturing costs over the LED suggested by Japanese Unexamined Patent Publication No. 2002-217450. This prior art device has a spaced arrangement of small alloy-made contact regions between main semiconductor region and reflector layer. The FIG. 2 LED according to the invention has no such contact regions, permitting the reflector layer 20 to make direct contact with one complete major surface of the main semiconductor region 3 as well as with that of the substrate 1. This inventive device is therefore capable of reflecting a greater proportion of the light, and is less in forward voltage requirement, than the prior art. It is also manufacturable more cheaply than the prior art because of the absence of the contact regions. A further reduction in manufacturing cost is possible by employing the same silver-base alloy for both anode overlay 10 and reflector layer 20.

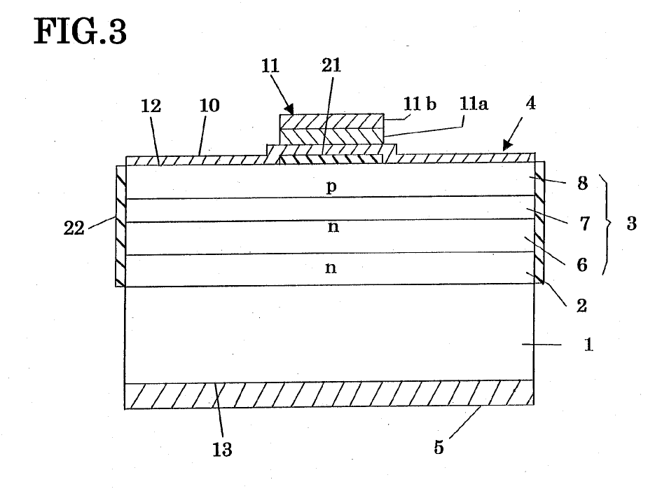

### Embodiment of FIG. 3

The LED shown here features a current blocking layer 21 and protective covering 22. All the other details of construction are as set forth with reference to FIG. 1. The current blocking layer 21 is placed between main semiconductor region 3 and anode overlay 10 and in register with the bonding pad. The current blocking layer 21 is made from silicon oxide or like electrically insulating material for blocking current flow. Although shown to be of the same shape and size as the bonding pad 11 as seen in a plan view, the current blocking layer 21 could be of any shape or size only if placed at least partly in register with the bonding pad.

Were it not for the current blocking layer 21, the current would flow from the bonding pad 11 down into the underlying part of the active layer 7 thereby causing light to be generated there. The light thus generated would be mostly intercepted by the bonding pad 11 and so wasted. The current blocking layer 21 of insulating material functions to block current flow from the bonding pad 11 into the underlying part of the active layer 7 and so to cause a correspondingly greater amount of current to flow from the anode overlay 10 down into the other part of the main semiconductor region 3 which is out of register with the bonding pad. This LED is thus bound to operate more efficiently to emit light of higher intensity than in the absence of the current blocking layer 21. The current blocking layer 21 could be used with the LED of FIG. 2.

The protective covering 22 envelopes the sides of the buffer layer 2 and main semiconductor region 3. This covering is made from an electrically insulating material, preferably from the same material as the current blocking layer 21. It is of course understood that the anode overlay 10 is made from any of the same silver-base alloys as set forth in conjunction with its FIG. 1 counterpart and so offers the same advantages therewith. The protective covering 22 could be used with the LED of FIG. 2.

### Possible Modifications

Notwithstanding the foregoing detailed disclosure it is not desired that the present invention be limited by the exact showings of the drawings or the description thereof. The following is a brief list of possible modifications, alterations or adaptations of the illustrated embodiments of the invention which are all believed to fall within the purview of the claims annexed hereto:
1. The silver-base alloys hereby suggested lend themselves to use for the electrodes of a variety of nitride semiconductor devices other than LEDs, such as transistors, field-effect transistors, high-electron-mobility transistors, lasers, photodetectors, and solar cells.
2. A buffer layer of AlInGaN or other composition could be interposed between the reflector layer 20, FIG. 2, and the n-type cladding 6 of the main semiconductor region 3.
3. The electroconductive silicon substrate 1 of all the embodiments is replaceable by other electroconductive substrates such as those of metals or those composed principally of SiC, or by insulating substrates such as those of sapphire.
4. The bottom electrode 5 of all the embodiments will be unnecessary if the substrate is metal made.
5. The constituent layers of the main semiconductor region 3 of all the embodiments are reversible in conductivity types.
6. The silver-base alloy sublayer 20_{b} of the FIG. 2 embodiment will be unnecessary if the substrate 1 is made from a metal capable of diffusive bonding with silver or silver-base alloy.
7. A reflector layer could be interposed between substrate 1 and cathode 5 in the embodiments of FIGS. 1 and 3.

What is claimed is:

1. A nitride semiconductor device comprising:
(a) a main semiconductor region made from a nitride; and
(b) an electrode formed on the main semiconductor region, the electrode being made from a silver-base alloy containing at least one additive selected from the group consisting of gold, copper, palladium, neodymium, silicon, iridium, nickel, tungsten, zinc, gallium, titanium, magnesium, yttrium, indium, and tin.

2. A nitride semiconductor device as defined in claim 1, wherein the additive is contained in the silver-base alloy in a proportion ranging from 0.5 percent by weight to 10 percent by weight.

3. A nitride semiconductor device comprising:
(a) a main semiconductor region made from a nitride; and
(b) an electrode formed on the main semiconductor region, the electrode being made from a silver-base alloy containing at least one first additive selected from the group consisting of gold, copper, palladium, iridium and nickel, and at least one second additive selected from the group consisting of neodymium, silicon, tungsten, zinc, gallium, titanium, magnesium, yttrium, indium, and tin.

4. A nitride semiconductor device as defined in claim 3, wherein the first and the second additives are each contained in the silver-base alloy in a proportion ranging from 0.5 percent by weight to 10 percent by weight with respect to that of silver, and wherein the first and the second additives are contained in the silver-base alloy in a total proportion ranging from 0.5 percent by weight to 10 percent by weight with respect to that of silver.

5. A light-emitting diode comprising:
(a) a light-generating semiconductor region having a plurality of nitride semiconductor layers for generating light; and
(b) an electrode made from a silver-base alloy and formed on the light-generating semiconductor region to a thickness capable of transmitting the light generated in the light-generating semiconductor region, the silver-base alloy containing at least one additive selected from the group consisting of gold, copper, palladium, neodymium, silicon, iridium, nickel, tungsten, zinc, gallium, titanium, magnesium, yttrium, indium, and tin.

6. A light-emitting diode as defined in claim 5, wherein the electrode is from one nanometer to 20 nanometers thick.

7. A light-emitting diode comprising:
(a) a light-generating semiconductor region having a plurality of nitride semiconductor layers for generating light; and
(b) an electrode formed on the light-generating semiconductor region, the electrode being made from a silver-base alloy containing at least one first additive selected from the group consisting of gold, copper, palladium, iridium and nickel, and at least one second additive selected from the group consisting of neodymium, silicon, tungsten, zinc, gallium, titanium, magnesium, yttrium, indium, and tin.

8. A light-emitting diode as defined in claim 7, wherein the electrode is from one nanometer to 20 nanometers thick.

9. A light-emitting diode as defined in claim 7, wherein the first and the second additives are each contained in the silver-base alloy in a proportion ranging from 0.5 percent by weight to 10 percent by weight with respect to that of silver, and wherein the first and the second additives are contained in the silver-base alloy in a total proportion ranging from 0.5 percent by weight to 10 percent by weight with respect to that of silver.

10. A light-emitting diode comprising:
(a) a light-generating semiconductor region having a plurality of nitride semiconductor layers for generating light, the light-generating semiconductor region having a pair of opposite major surfaces;
(b) a substrate held against one of the pair of opposite major surfaces of the light-generating semiconductor region;
(c) an electrode on the other major surface of the light-generating semiconductor region, the electrode being made from a silver-base alloy containing at least one first additive selected from the group consisting of gold, copper, palladium, iridium and nickel, and at least one second additive selected from the group consisting of neodymium, silicon, tungsten, zinc, gallium, titanium, magnesium, yttrium, indium, and tin; and
(d) an electroconductive reflector layer interposed between the substrate and the light-generating semiconductor region for reflecting the light from the light-generating semiconductor region toward said other major surface of the light-generating semiconductor region, the reflector layer being made from a silver-base alloy.

11. A light-emitting diode as defined in claim 10, wherein the electrode is from one nanometer to 20 nanometers thick.

12. A light-emitting diode as defined in claim 10, wherein the additive is contained in the silver-base alloy in a proportion ranging from 0.5 percent by weight to 10 percent by weight.
